(19) United States
(12) Patent Application Publication
(10) Pub. No.: US 2021/0071297 A1
(43) Pub. Date: Mar. 11, 2021

(54) SUBSTRATE PROCESSING APPARATUS

(71) Applicant: KOKUSAI ELECTRIC CORPORATION, Tokyo (JP)

(72) Inventors: Hidehiro YANAI, Toyama-shi (JP); Tadashi TAKASAKI, Toyama-shi (JP)

(73) Assignee: KOKUSAI ELECTRIC CORPORATION, Tokyo (JP)

(21) Appl. No.: 16/812,505

(22) Filed: Mar. 9, 2020

(30) Foreign Application Priority Data
Sep. 10, 2019 (JP) 2019-164250

(51) Int. Cl. C23C 16/458; C23C 16/455; C23C 16/44; C23C 16/34; H01L 21/02; H01L 21/687

(52) U.S. Cl. CPC C23C 16/4584; C23C 16/45563; C23C 16/4412; H01L 21/68764; H01L 21/0217; H01L 21/02271; C23C 16/345

(57) ABSTRACT

Described herein is a technique capable of enhancing uniformity of a film formed by a rotary type apparatus. According to one aspect of the technique, there is provided a substrate processing apparatus including: a process vessel provided with process regions where the substrate is processed; a rotary table provided in the process vessel to be rotatable about a point outside the substrate to enable the substrate on the rotary table to sequentially pass through the process regions; and a gas supply nozzle including: a forward path portion provided in at least one of the process regions and extending from a wall of the process vessel toward a center portion of the rotary table; and a return path portion connected with the forward path portion via a bent portion and extending from the center portion of the rotary table toward the wall of the process vessel.

### CROSS-REFERENCE TO RELATED PATENT APPLICATION

This non-provisional U.S. patent application claims priority under 35 U.S.C. § 119 of Japanese Patent Application No. 2019-164250, filed on Sep. 10, 2019, the entire contents of which are hereby incorporated by reference.

### BACKGROUND

### 1. Field

The present disclosure relates to a substrate processing apparatus.

### 2. Description of the Related Art

As an apparatus of processing a semiconductor substrate, a rotary type apparatus may be used. For example, according to the rotary type apparatus, a plurality of substrates are arranged on a substrate support of the rotary type apparatus along a circumferential direction, and various gases are supplied onto the plurality of the substrates by rotating the substrate support. In addition, a vertical type apparatus may also be used. For example, according to the vertical type apparatus, a source gas is supplied onto a plurality of substrates stacked in the vertical type apparatus by using a source gas nozzle extending along a stacking direction of the plurality of the substrates.

According to the rotary type apparatus, for example, the plurality of the substrates including a substrate of 300 mm are arranged along the circumferential direction, and a heat treatment process may be performed to the plurality of the substrates. Therefore, for example, when the source gas is supplied by using an I-shaped nozzle, the source gas supplied to the plurality of the substrates may be thermally decomposed in the I-shaped nozzle as a temperature of the apparatus increases. As a result, the characteristics of a film formed on a surface of each of the substrates may vary along a radial direction of the substrate.

### SUMMARY

Described herein is a technique capable of improving a uniformity of the characteristics of a film formed on a substrate by a rotary type apparatus.

According to one aspect of the technique of the present disclosure, there is provided a substrate processing apparatus configured to process a substrate by supplying a process gas, the substrate processing apparatus including: a process vessel provided with a plurality of process regions in which the substrate is processed; a rotary table provided in the process vessel and configured to be rotated about a portion provided outside the substrate so that the substrate is sequentially passed through the plurality of the process regions; and a gas supply nozzle including: a forward path portion provided for at least one of the plurality of the process regions and configured to extend from a wall of the process vessel toward a center side of the rotary table; and a return path portion communicated with the forward path portion via a bent portion and configured to extend from the center side of the rotary table toward the wall of the process vessel.

### BRIEF DESCRIPTION OF THE DRAWINGS

FIG. 1 schematically illustrates a horizontal cross-section of a reactor of a substrate processing apparatus according to a first embodiment described herein.

FIG. 2 schematically illustrates a cross-section taken along the line A-A′ of the reactor of the substrate processing apparatus according to the first embodiment shown in FIG. 1.

FIG. 3 schematically illustrates a substrate support mechanism according to the first embodiment described herein.

FIG. 4A schematically illustrates a source gas supply part according to the first embodiment described herein, FIG. 4B schematically illustrates a reactive gas supply part according to the first embodiment described herein, FIG. 4C schematically illustrates a first inert gas supply part according to the first embodiment described herein and FIG. 4D schematically illustrates a second inert gas supply part according to the first embodiment described herein.

FIG. 5 schematically illustrates a nozzle according to the first embodiment described herein.

FIG. 6 schematically illustrates a thermal decomposition amount of a source gas flowing in the nozzle according to the first embodiment described herein.

FIG. 7 is a block diagram schematically illustrating a configuration of a controller and related components of the substrate processing apparatus according to the first embodiment described herein.

FIG. 8 is a flow chart schematically illustrating a substrate processing according to the first embodiment described herein.

FIG. 9 is a flow chart schematically illustrating a film-forming step of the substrate processing according to the first embodiment described herein.

FIG. 10 schematically illustrates a horizontal cross-section of a reactor of a substrate processing apparatus and a nozzle of the reactor according to a second embodiment described herein.

FIG. 11 schematically illustrates a horizontal cross-section of a reactor of a substrate processing apparatus and a nozzle of the reactor according to a third embodiment described herein.

FIG. 12 schematically illustrates a horizontal cross-section of a reactor of a substrate processing apparatus and a nozzle of the reactor according to a fourth embodiment described herein.

FIGS. 13A through 13E schematically illustrate nozzles according to a fifth through a ninth embodiment described herein, respectively.

### DETAILED DESCRIPTION

### First Embodiment

(1) Configuration of Substrate Processing Apparatus

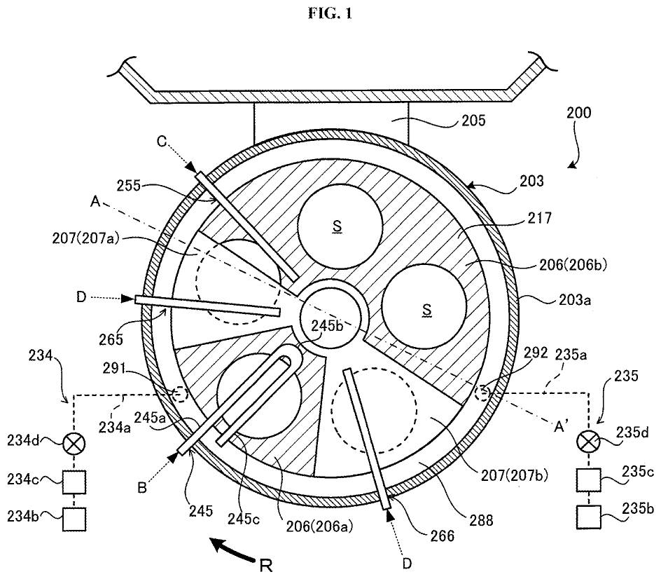

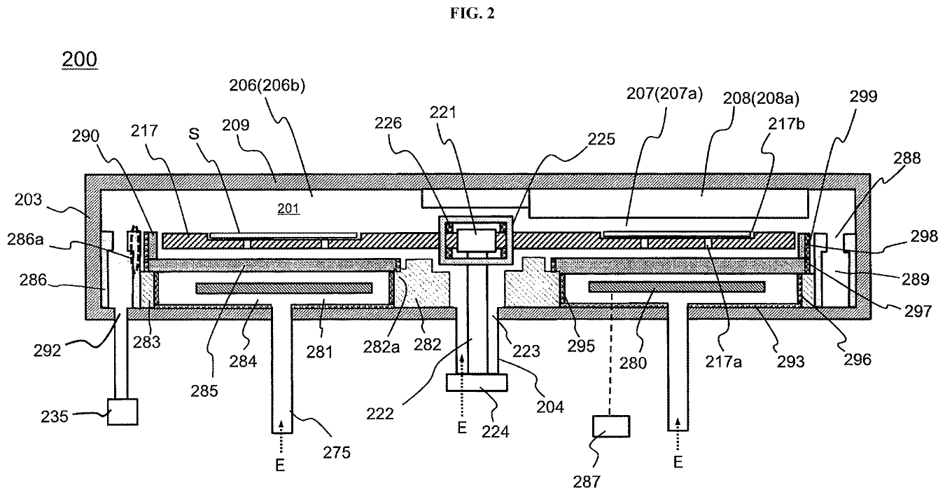

As shown in FIGS. 1 and 2, a reactor 200 of a substrate processing apparatus (also referred to a “rotary type apparatus”) includes a process vessel 203 which is a cylindrical sealed vessel (hermetic vessel). For example, the process vessel 203 is made of a material such as stainless steel (SUS) and an aluminum alloy. A process chamber 201 in which a plurality of substrates including a substrate S are processed is provided in the process vessel 203. A gate valve 205 is connected to the process vessel 203. The substrate S is loaded (transferred) into or unloaded (transferred) out of the process vessel 203 through the gate valve 205.

The process chamber 201 includes a process region 206 to which a process gas such as a source gas and a reactive gas is supplied and a purge region 207 to which a purge gas is supplied. According to the first embodiment, the process region 206 and the purge region 207 are alternately arranged along the circumferential direction. For example, a first process region 206a, a first purge region 207a, a second process region 206b, and a second purge region 207b are arranged along the circumferential direction in this order. As described later, for example, the source gas is supplied into the first process region 206a, the reactive gas is supplied into the second process region 206b, and an inert gas is supplied into the first purge region 207a and the second purge region 207b. As a result, a predetermined processing (substrate processing) is performed to the substrate S in accordance with the gas supplied into each region.

The purge region 207 is configured to spatially separate the first process region 206a and the second process region 206b. A ceiling 208 of the purge region 207 is disposed lower than a ceiling 209 of the process region 206. Specifically, a ceiling 208a is provided at the first purge region 207a, and a ceiling 208b is provided at the second purge region 207b. By lowering each of the ceilings such as the ceiling 208a and the ceiling 208b, it is possible to increase a pressure of a space of the purge region 207. By supplying the purge gas into the space of the purge region 207, it is possible to partition the adjacent process region 206 (that is, the first process region 206a and the second process region 206b). In addition, the purge gas is configured to remove excess gases on the substrate S.

A rotary table 217 configured to be rotatable is provided at a center portion of the process vessel 203. A rotating shaft of the rotary table 217 is provided at a center of the process vessel 203. For example, the rotary table 217 is made of a material such as quartz, carbon and silicon carbide (SiC) such that the substrate S is not affected by the metal contamination.

The rotary table 217 is configured such that the plurality of the substrates (for example, five substrates) including the substrate S can be arranged within the process vessel 203 on the same plane and along the same circumference along a rotational direction R. In the present specification, the term “the same plane” is not limited to a perfectly identical plane but may also include a case where, for example, the plurality of the substrates including the substrate S are arranged so as not to overlap with each other when viewed from above.

A plurality of concave portions 217b are provided on a surface of the rotary table 217 to support the plurality of the substrates including the substrate S. The number of the concave portions 217b is equal to the number of the substrates to be processed. For example, the plurality of the concave portions 217b are arranged at the same distance from a center of the rotary table 217, and are arranged along the same circumference at equal intervals (for example, 72° intervals). In FIG. 1, the illustration of the plurality of the concave portions is omitted for simplification.

Each of the concave portions 217b is of a circular shape when viewed from above and of a concave shape when viewed by a vertical cross-section thereof. It is preferable that a diameter of each of the concave portions 217b is slightly greater than a diameter of the substrate S. A plurality of substrate placing surfaces are provided respectively at the bottoms of the plurality of the concave portions. For example, the substrate S may be placed on the substrate placing surface by being placed on one of the concave portions 217b. Through-holes 217a penetrated by pins 219 described later are provided at each of the substrate placing surfaces.

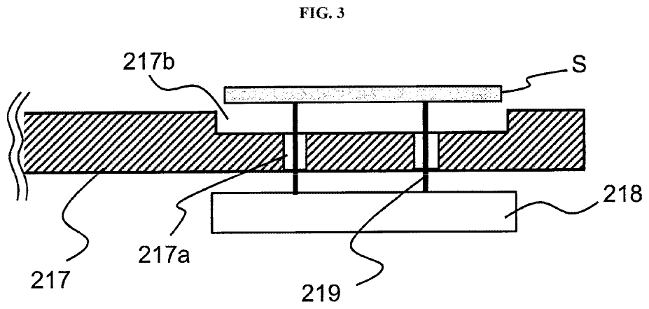

A substrate support mechanism 218 shown in FIG. 3 is provided in the process vessel 203 at a position below the rotary table 217 and facing the gate valve 205. The substrate support mechanism 218 includes the pins 219 configured to elevate or lower the substrate S and to support a back surface of the substrate S when the substrate S is loaded into or unloaded out of the process chamber 201. The pins 219 may be of an extendable configuration. For example, the pins 219 may be accommodated in a main body of the substrate support mechanism 218. When the substrate S is transferred, the pins 219 are extended and pass through the through-holes 217a. Thereby, the substrate S is supported by the pins 219. Thereafter, by moving front ends of the pins 219 downward, the substrate S is placed on one of the concave portions 217b. For example, the substrate support mechanism 218 is fixed to the process vessel 203. The substrate support mechanism 218 may be embodied by any configuration as long as the pins 219 can be inserted into the through-holes 217a when the substrate S is placed, and may also be fixed to an inner peripheral convex portion 282 or an outer peripheral convex portion 283 described later.

The rotary table 217 is fixed to a core portion 221. The core portion 221 is provided at the center of the rotary table 217 and configured to fix the rotary table 217. Since the core portion 221 supports the rotary table 217, for example, the core portion 221 is made of a metal that can withstand the weight of the rotary table 217. A shaft 222 is provided below the core portion 221. The shaft 222 supports the core portion 221.

A lower portion of the shaft 222 penetrates a hole 223 provided at a bottom of the process vessel 203, and a vessel 204 capable of hermetically sealing the shaft 222 covers a periphery of the lower portion of the shaft 222. The vessel 204 is provided outside the process vessel 203. A lower end of the shaft 222 is connected to a rotating part (also referred to as a “rotating mechanism”) 224. The rotating part 224 is provided with components such as a rotating shaft (not shown) and a motor (not shown), and is configured to rotate the rotary table 217 according to instructions from a controller 300 described later. That is, the controller 300 controls the rotating part 224 to rotate the rotary table 217 about a point (for example, about the center of the core portion 221) provided outside the substrate S, so that the substrate S sequentially passes through the first process region 206a, the first purge region 207a, the second process region 206b, and the second purge region 207b in this order.

A quartz cover 225 is provided so as to cover the core portion 221. That is, the quartz cover 225 is provided between the core portion 221 and the process chamber 201. The quartz cover 225 is configured to cover the core portion 221 via a space between the core portion 221 and the process chamber 201. For example, the quartz cover 225 is made of a material such as quartz and SiC such that the substrate S is not affected by the metal contamination. The core portion 221, the shaft 222, the rotating part 224 and the quartz cover 225 may be collectively referred to as a “support part”.

A heater mechanism 281 is provided below the rotary table 217. A plurality of heaters including a heater 280 serving as a heating device are embedded in the heater mechanism 281. The plurality of heaters including the heater 280 are configured to heat the plurality of the substrate including the substrate S placed on the rotary table 217, respectively. The plurality of the heaters including the heater 280 are arranged along the same circumference in accordance with a shape of the process vessel 203.

The heater mechanism 281 is constituted mainly by: the inner peripheral convex portion 282 provided on the bottom of the process vessel 203 and on a center portion of the process vessel 203; the outer peripheral convex portion 283 disposed outside the heater 280; and the heater 280. The inner peripheral convex portion 282, the heater 280 and the outer peripheral convex portion 283 are arranged concentrically. A space 284 is provided between the inner peripheral convex portion 282 and the outer peripheral convex portion 283. The heater 280 is disposed in the space 284. Since the inner peripheral convex portion 282 and the outer peripheral convex portion 283 are fixed to the process vessel 203, the inner peripheral convex portion 282 and the outer peripheral convex portion 283 may be considered as a part of the process vessel 203.

While the first embodiment will be described by way of an example in which the heater 280 of a circular shape is used, the first embodiment is not limited thereto as long as the substrate S can be heated by the heater 280. For example, the heater 280 may be divided into a plurality of auxiliary heater structures.

A flange 282a is provided at an upper portion of the inner peripheral convex portion 282 to face the heater 280. A window 285 is supported on upper surfaces of the flange 282a and the outer peripheral convex portion 283. For example, the window 285 is made of a material capable of transmitting the heat generated by the heater 280 such as quartz. The window 285 is fixed by interposing the window 285 between the inner peripheral convex portion 282 and an upper portion 286a of an exhaust structure 286 described later.

A heater controller (also referred to as a “heater temperature controller”) 287 is connected to the heater 280. The heater controller 287 is electrically connected to the controller 300 described later, and is configured to control the supply of the electric power to the heater 280 according to an instruction from the controller 300 to perform a temperature control.

An inert gas supply pipe 275 communicating with the space 284 is provided at the bottom of the process vessel 203. The inert gas supply pipe 275 is connected to a second inert gas supply part 270 described later. The inert gas supplied through the second inert gas supply part 270 is supplied to the space 284 through the inert gas supply pipe 275. By setting the space 284 to an inert gas atmosphere, it is possible to prevent the process gas from entering the space 284 through a gap in the vicinity of the window 285.

The exhaust structure 286 made of a metal is disposed (provided) between an outer peripheral surface of the outer peripheral convex portion 283 and an inner peripheral surface of the process vessel 203. The exhaust structure 286 includes an exhaust groove 288 and an exhaust buffer space 289. Each of the exhaust groove 288 and the exhaust buffer space 289 is of a ring shape in accordance with the shape of the process vessel 203.

A portion of the exhaust structure 286 which is not in contact with the outer peripheral convex portion 283 is referred to as the upper portion 286a. As described above, the upper portion 286a is configured to fix the window 285 together with the inner peripheral convex portion 282.

According to the rotary type apparatus (also referred to as a “rotary type substrate processing apparatus”) as in the first embodiment, it is preferable that a height of the substrate S is same as or close to a height of an exhaust port described later. When the height of the exhaust port is lower than that of the substrate S, a turbulent flow of the gas may occur at an end portion of the rotary table 217. On the other hand, it is possible to suppress the occurrence of the turbulent flow by setting the height of the substrate S to be the same as or close to the height of an exhaust port.

According to the first embodiment, an upper end of the exhaust structure 286 is provided at the same height as the rotary table 217. When the upper end of the exhaust structure 286 is provided at the same height as the rotary table 217, as shown in FIG. 2, a protrusion of the upper portion 286a protrudes from the window 285. To prevent the particles from diffusing, a quartz cover 290 is provided to cover the protrusion of the upper portion 286a. Without the quartz cover 290, the gas may come into contact with the upper portion 286a, corrode the upper portion 286a and generate the particles in the process chamber 201. A space 299 is provided between the quartz cover 290 and the upper portion 286a.

An exhaust port 291 and an exhaust port 292 are provided at a bottom of the exhaust structure 286. The source gas supplied into the first process region 206a and the purge gas supplied through an upstream side of the first process region 206a are mainly exhausted through the exhaust port 291. The reactive gas supplied into the second process region 206b and the purge gas supplied through an upstream side of the second process region 206b are mainly exhausted through the exhaust port 292. Each of the gases describe above is exhausted through the exhaust port 291 and the exhaust port 292 via the exhaust groove 288 and the exhaust buffer space 289.

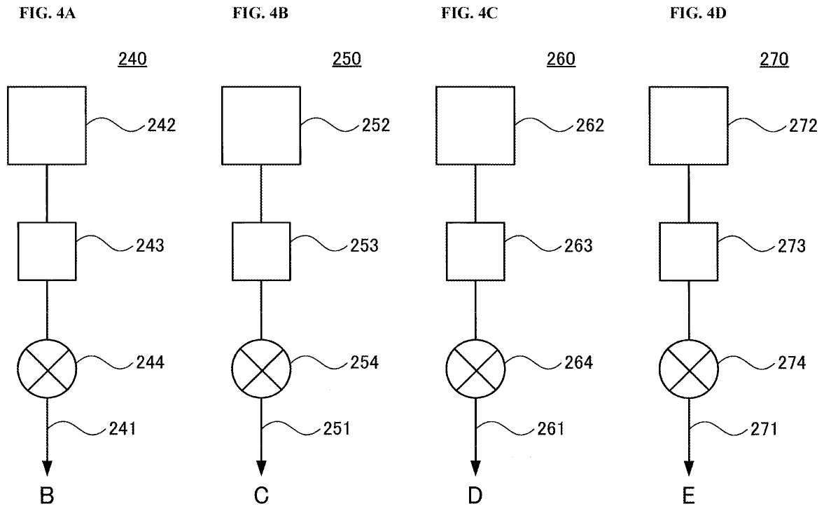

Subsequently, a source gas supply part (also referred to as a “source gas supply mechanism” or a “source gas supply system”) 240 will be described with reference to FIGS. 1 and 4A. As shown in FIG. 1, a nozzle 245 serving as a gas supply nozzle extending toward the center of the process vessel 203 penetrates a side of the process vessel 203. The nozzle 245 is provided in the first process region 206a. A downstream end of a gas supply pipe 241 is connected to the nozzle 245. The nozzle 245 will be described later in detail.

A source gas supply source 242, a mass flow controller (MFC) 243 serving as a flow rate controller (also referred to as a “flow rate control mechanism”) and a valve 244 serving as an opening/closing valve are provided at the gas supply pipe 241 in the sequential order from an upstream side to a downstream side of the gas supply pipe 241.

The source gas is supplied into the first process region 206a through the nozzle 245 via the gas supply pipe 241 provided with the MFC 243 and the valve 244.

In the present specification, the source gas is one of process gases, and serves as a source when a film is formed. The source gas contains at least one element constituting the film. For example, the source gas contains at least one element among silicon (Si), titanium (Ti), tantalum (Ta), hafnium (Hf), zirconium (Zr), ruthenium (Ru), nickel (Ni), tungsten (W) and molybdenum (Mo).

Specifically, according to the first embodiment, for example, dichlorosilane (Si₂H₂Cl₂) gas may be used as the source gas. When a source of the source gas is a gaseous state under the normal temperature (room temperature), a gas mass flow controller is used as the MFC 243.

The source gas supply part (also referred to as a “first gas supply system” or a “first gas supply part”) 240 is constituted mainly by the gas supply pipe 241, the MFC 243, the valve 244 and the nozzle 245. The source gas supply part 240 may further include the source gas supply source 242.

Subsequently, a reactive gas supply part (also referred to as a “reactive gas supply mechanism” or a “reactive gas supply system”) 250 will be described with reference to FIGS. 1 and 4B. As shown in FIG. 1, a nozzle 255 extending toward the center of the process vessel 203 penetrates a side of the process vessel 203. The nozzle 255 is provided in the second process region 206b.

A gas supply pipe 251 is connected to the nozzle 255. A reactive gas supply source 252, an MFC 253 and a valve 254 are provided at the gas supply pipe 251 in the sequential order from an upstream side to a downstream side of the gas supply pipe 251.

The reactive gas is supplied into the second process region 206b through the nozzle 255 via the gas supply pipe 251 provided with the MFC 253 and the valve 254.

In the present specification, the reactive gas is one of the process gases, and refers to a gas that reacts with a first layer formed on the substrate S by supplying the source gas. For example, the reactive gas may include at least one among ammonia (NH₃) gas, nitrogen (N₂) gas, hydrogen (H₂) gas and oxygen (0₂) gas. Specifically, according to the first embodiment, for example, the NH₃ gas may be used as the reactive gas.

The reactive gas supply part (also referred to as a “second gas supply system” or a “second gas supply part”) 250 is constituted mainly by the gas supply pipe 251, the MFC 253, the valve 254 and the nozzle 255. The reactive gas supply part 250 may further include the reactive gas supply source 252.

Subsequently, a first inert gas supply part (also referred to as a “first inert gas supply mechanism” or a “first inert gas supply system”) 260 will be described with reference to FIGS. 1 and 4C. As shown in FIG. 1, each of a nozzle 265 and a nozzle 266 extending toward the center of the process vessel 203 penetrates a side of the process vessel 203. The nozzle 265 is provided in the first purge region 207a. For example, the nozzle 265 may be fixed to the ceiling 208a of the first purge region 207a. The nozzle 266 is provided in the second purge region 207b. For example, the nozzle 266 may be fixed to the ceiling 208b of the second purge region 207b.

A downstream end of an inert gas supply pipe 261 is connected to the nozzle 265 and the nozzle 266. An inert gas supply source 262, an MFC 263 and a valve 264 are provided at the inert gas supply pipe 261 in the sequential order from an upstream side to a downstream side of the inert gas supply pipe 261. The inert gas is supplied into the first purge region 207a and the second purge region 207b through the nozzle 265 and the nozzle 266 via the inert gas supply pipe 261 provided with the MFC 263 and the valve 264. The inert gas supplied into the first purge region 207a and the second purge region 207b serves as a purge gas.

The first inert gas supply part 260 is constituted mainly by the inert gas supply pipe 261, the MFC 263, the valve 264, the nozzle 265 and the nozzle 266. The first inert gas supply part 260 may further include the inert gas supply source 262.

Subsequently, the second inert gas supply part (also referred to as a “second inert gas supply mechanism” or a “second inert gas supply system”) 270 will be described with reference to FIGS. 2 and 4D. A downstream end of an inert gas supply pipe 271 is connected to the inert gas supply pipe 275. An inert gas supply source 272, an MFC 273 and a valve 274 are provided at the inert gas supply pipe 271 in the sequential order from an upstream side to a downstream side of the inert gas supply pipe 271. The inert gas is supplied into the space 284 and the vessel 204 through the inert gas supply pipe 275 via the inert gas supply pipe 271 provided with the MFC 273 and the valve 274.

The inert gas supplied into the vessel 204 is exhausted through the exhaust groove 288 via a space between the rotary table 217 and the window 285. With such a structure, it is possible to prevent the source gas and the reactive gas from flowing into the space between the rotary table 217 and the window 285.

The second inert gas supply part 270 is constituted mainly by the inert gas supply pipe 271, the MFC 273, the valve 274, and the inert gas supply pipe 275. The second inert gas supply part 270 may further include the inert gas supply source 272.

In the present specification, the inert gas may include at least one among nitrogen (N₂) gas and a rare gas such as helium (He) gas, neon (Ne) gas and argon (Ar) gas. Specifically, according to the first embodiment, for example, the N₂ gas may be used as the inert gas.

As shown in FIG. 1, the exhaust port 291 and the exhaust port 292 are provided at the process vessel 203. The exhaust port 291 is provided at a location downstream along the rotational direction R in the first process region 206a. The source gas and the inert gas are mainly exhausted through the exhaust port 291.

An exhaust pipe 234a which is a part of an exhaust part (also referred to as an “exhaust mechanism” or an “exhaust system”) 234 is provided so as to communicate with the exhaust port 291. A vacuum pump 234b serving as a vacuum exhaust device is connected to the exhaust pipe 234a via a valve 234d serving as an opening/closing valve and an APC (Automatic Pressure Controller) valve 234c serving as a pressure controller (also referred to as a “pressure adjusting mechanism”). The vacuum pump 234b is configured to vacuum-exhaust an inner atmosphere of the process chamber 201 such that an inner pressure of the process chamber 201 reaches a predetermined pressure (vacuum degree).

The exhaust pipe 234a, the valve 234d and the APC valve 234c are collectively referred to as the exhaust part 234. The exhaust part 234 may further include the vacuum pump 234b.

As shown in FIGS. 1 and 2, an exhaust part (also referred to as an “exhaust mechanism” or an “exhaust system”) 235 is provided so as to communicate with the exhaust port 292. The exhaust port 292 is provided at a location downstream along the rotational direction R in the second process region 206b. The reactive gas and the inert gas are mainly exhausted through the exhaust port 292.

An exhaust pipe 235a which is a part of the exhaust part 235 is provided so as to communicate with the exhaust port 292. A vacuum pump 235b is connected to the exhaust pipe 235a via a valve 235d and an APC valve 235c. The vacuum pump 235b is configured to vacuum-exhaust the inner atmosphere of the process chamber 201 such that the inner pressure of the process chamber 201 reaches a predetermined pressure (vacuum degree).

The exhaust pipe 235a, the valve 235d and the APC valve 235c are collectively referred to as the exhaust part 235. The exhaust part 235 may further include the vacuum pump 235b.

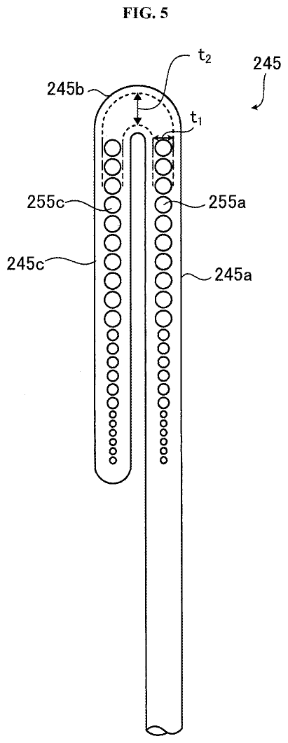

Subsequently, the nozzle 245 will be described in detail with reference to FIG. 5. For example, the nozzle 245 is used as a part of the source gas supply part 240 configured to supply a silicon (Si)-based Si₂H₂Cl₂ gas serving as the source gas to the first process region 206a.

The nozzle 245 may be embodied by a U-shaped nozzle. The nozzle 245 is provided in the first process region 206a. For example, the nozzle 245 is made of a cleaning resistant material such as quartz and ceramics. The nozzle 245 includes: a forward path portion 245a connected to and communicated with the gas supply pipe 241; a bent portion 245b bent from the forward path portion 245a to communicate with the forward path portion 245a; and a return path portion 245c connected to and communicated with the bent portion 245b. That is, the bent portion 245b connects the forward path portion 245a and the return path portion 245c in a U-shape. In addition, the forward path portion 245a and the return path portion 245c extend in parallel with each other.

A plurality of holes 255a of a round shape are provided at the forward path portion 245a to vertically face the substrate S on the rotary table 217. A diameter of each of the plurality of the holes 255a gradually increases from an upstream side to a downstream side of a gas flow in the forward path portion 245a. That is, the diameter of each of the plurality of the holes 255a gradually increases as it approaches the bent portion 245b (that is, as a distance from the bent portion 245b decreases). With such a configuration, it is possible to increase an amount of thermally decomposed gas supplied to the center portion of the rotary table 217. Thereby, it is possible to form the gas flow of the decomposed gas flowing from the center portion of the rotary table 217 toward an outside of the rotary table 217.

A plurality of holes 255c of a round shape are provided at the return path portion 245c to vertically face the substrate S on the rotary table 217. A diameter of each of the plurality of the holes 255c gradually decreases from an upstream side to a downstream side of a gas flow in the return path portion 245c. That is, the diameter of each of the plurality of the holes 255c gradually decreases as it moves away from the bent portion 245b (that is, as a distance from the bent portion 245b increases). With such a configuration, it is possible to reduce an amount of the decomposed gas supplied to the outer peripheral portion of the rotary table 217.

As shown in FIG. 1, the forward path portion 245a extends along a radial direction of the rotary table 217 from a wall 203a of the process vessel 203 toward the center portion of the rotary table 217. The return path portion 245c extends along the radial direction of the rotary table 217 from the center portion of the rotary table 217 toward the wall 203a of the process vessel 203. In other words, the forward path portion 245a and the return path portion 245c of the nozzle 245 extend along the radial direction of the rotary table 217 from one end to the other end and vice versa, respectively, with respect to the substrate S on the rotary table 217. Thereby, it is possible to easily adjust a film distribution.

The bent potion 245b is bent from the forward path portion 245a to the return path portion 245c along a direction opposite to the rotational direction R, and the return path portion 245c extends from the bent potion 245b toward the outer periphery of the rotary table 217. The return path portion 245c is displaced circumferentially from the forward path portion 245a along a direction opposite to the rotational direction R of the rotary table 217. Thereby, it is possible to lengthen a residence time of the source gas in the first process region 206a. The bent portion 245b is disposed at a position vertically facing an outside of the substrate S placed on the rotary table 217. That is, the bent portion 245b does not overlap with the substrate S placed on the rotary table 217 when viewed from above. Since the source gas ejected from the nozzle 245 strongly hits a surface of the bent portion 245b, by-products are adhered to the bent portion 245b in more amount than to other portions. If the bent portion 245b were disposed at a position vertically facing the substrate S, foreign materials originated from the by-product falling from its opening may adhere to the substrate S. Therefore, it is preferable that the bent portion 245b is disposed at such position as it does not vertically face the substrate S.

As described above, the diameters of the holes 255a become greater at locations vertically above the center portion of the rotary table 217 than at locations vertically above an outer peripheral portion of the rotary table 217. In addition, the diameters of the holes 255c become greater at locations vertically above the center portion of the rotary table 217 than at locations vertically above the outer peripheral portion of the rotary table 217.

A front end of the forward path portion 245a, which is at a downstream end of the gas flow in the forward path portion 245a, extends beyond an edge of the substrate S placed on the rotary table 217. In addition, the plurality of the holes 255a are disposed along the radial direction of the rotary table 217 from a location vertically above an outside of the edge of the substrate S to a location vertically above an outside of the opposite edge of the substrate S. That is, some of the holes 255a are located to vertically face the substrate S on the rotary table 217, and the other of the holes 255a are located vertically above an outside of the substrate S on the rotary table 217. Thereby, it is possible to uniformly form the film on the entire portion of the substrate S including its edge portion.

A front end of the return path portion 245c, which is at a downstream end of the gas flow in the return path portion 245c, extends to the exhaust groove 288 provided outside an edge of the substrate S on the rotary table 217. In addition, the plurality of the holes 255c are arranged along the radial direction of the rotary table 217 from a location vertically above the outside of the edge of the substrate S to a location vertically above the outside of the opposite edge of the substrate S. That is, some of the holes 255c are located to vertically face the substrate S on the rotary table 217, and the other of the holes 255c are located vertically above the outside of the substrate S on the rotary table 217. Thereby, it is possible to uniformly form the film on the entire portion of the substrate S including its edge portion. In addition, the return path portion 245c is aligned in parallel with the forward path portion 245a, and the front end of the return path portion 245c (which is at the downstream end of the gas flow in the return path portion 245c) extends to the vicinity of the exhaust groove 288 connected to the exhaust port 291 configured to exhaust the source gas. Thereby, it is possible to shorten the residence time of the thermally decomposed source gas on the substrate S to thereby reduce its influence on a thickness of the film. That is, it is possible to improve a uniformity of the film formed on the substrate S. In addition, an opening may be provided at the front end of the return path portion 245c. Thus, the source gas supplied into the nozzle 245 is discharged without being clogged. In the present specification, the uniformity of the film refers to a uniformity of the film characteristics on a surface of the substrate S. For example, the film characteristics refer to the characteristics such as the thickness, a dielectric constant, insulation characteristics, an etching resistance and current leakage characteristics. Although in the first embodiment the uniformity of the thickness of the film is mainly described, it is also possible to improve the uniformity of other characteristics.

The plurality of the holes 255a of the forward path portion 245a are located at radial positions substantially same as those of the plurality of the holes 255c of the return path portion 245c with reference to the radial direction of the rotary table 217. Thereby, it is possible to adjust a gas supply amount in the radial direction of the rotary table 217, wherein the gas supply amount refers to the amount of the gas supplied to the rotary table 217.

An inner diameter t₂ of the bent portion 245b is greater than an inner diameter t₁ of the forward path portion 245a and the return path portion 245c. Thus, it is possible to reduce a pressure loss of the source gas at the bent portion 245b.

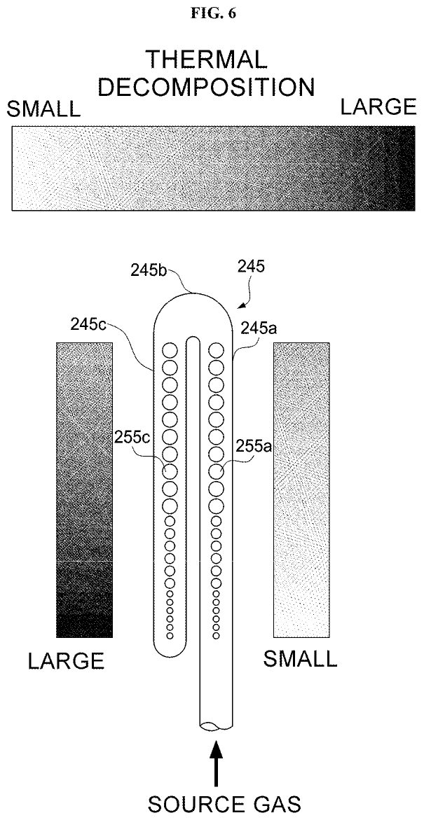

As a temperature of the apparatus (for example, an inner temperature of the process chamber 201) increases, the thermal decomposition of the source gas is accelerated in the radial direction of the substrate S in the nozzle 245, and propagates from the upstream side to the downstream side of the nozzle 245 in which the source gas flows. That is, as shown in FIG. 6, an amount of the thermal decomposition (also simply referred to as a “thermal decomposition amount”) of the source gas flowing in the nozzle 245 gradually increases from the upstream side to the downstream side of the nozzle 245 as the source gas flows from the upstream side to the downstream side of the nozzle 245. For example, when the thermal decomposition amount of the source gas supplied from a hole located at the most upstream position among the plurality of the holes 255a is zero (0) and the thermal decomposition amount of the source gas supplied from a hole located at the most downstream position among the plurality of the holes 255c is 10, the thermal decomposition amount of the source gas supplied to the substrate S is equalized as 5 along the radial direction. That is, the thermally decomposed source gas is uniformly supplied to the substrate S. Thereby, it is possible to improve the uniformity of the thickness of the film on the surface of the substrate S along the radial direction of the substrate S.

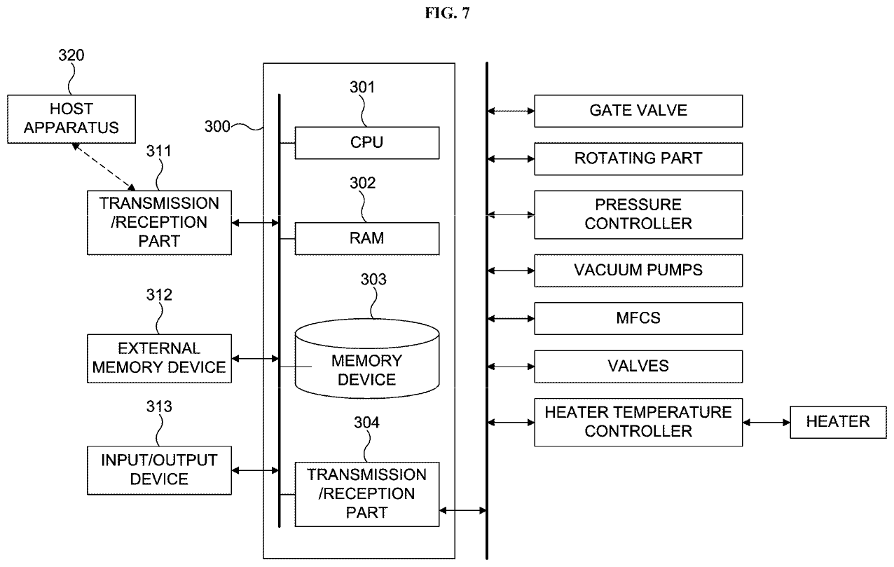

The reactor 200 includes the controller 300 configured to control the operations of the components of the substrate processing apparatus. As shown in FIG. 7, the controller 300 includes at least a CPU (Central Processing Unit) 301 serving as an arithmetic unit, a RAM (Random Access Memory) 302 serving as a temporary memory device, a memory device 303 and a transmission/reception part 304. The controller 300 is connected to the components of the substrate processing apparatus via the transmission/reception part 304, calls a program or a recipe from the memory device 303 in accordance with an instruction from a host controller or a user, and controls the operations of the components of the substrate processing apparatus according to the contents of the instruction. The controller 300 may be embodied by a dedicated computer or by a general-purpose computer. According to the first embodiment, for example, the controller 300 may be embodied by preparing an external memory device 312 storing the program and by installing the program onto the general-purpose computer using the external memory device 312. For example, the external memory device 312 may include a magnetic tape, a magnetic disk such as a flexible disk and a hard disk, an optical disk such as a CD and a DVD, a magneto-optical disk such as an MO and a semiconductor memory such as a USB memory (USB flash drive) and a memory card. The means for providing the program to the computer is not limited to the external memory device 312. For example, the program may be supplied to the computer (general-purpose computer) using communication means such as the Internet and a dedicated line. The program may be provided to the computer without using the external memory device 312 by receiving the information (that is, the program) from a host apparatus 320 via a transmission/reception part 311. In addition, a user can input an instruction to the controller 300 using an input/output device 313 such as a keyboard and a touch panel.

The memory device 303 or the external memory device 312 may be embodied by a non-transitory computer readable recording medium. Hereafter, the memory device 303 and the external memory device 312 are collectively referred to as the recording medium. In the present specification, the term “recording medium” may refer to only the memory device 303, may refer to only the external memory device 312 or may refer to both of the memory device 303 and the external memory device 312.

The CPU 301 is configured to read the control program from the memory device 303 and execute the read control program. Furthermore, the CPU 301 is configured to read the recipe such as a process recipe from the memory device 303 according to an operation command inputted from the input/output device 313. According to the contents of the read recipe, the CPU 301 may be configured to control the operations of the components of the substrate processing apparatus.

(2) Substrate Processing

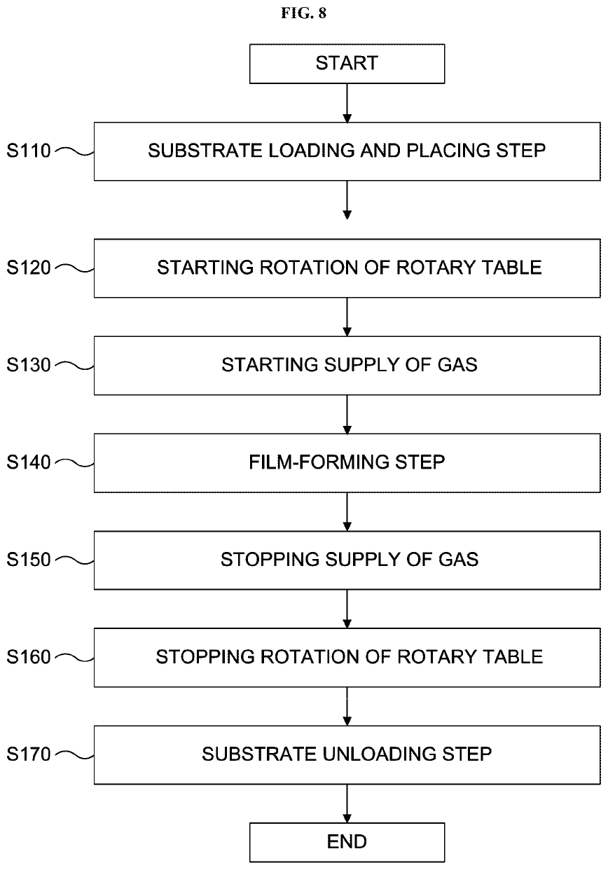

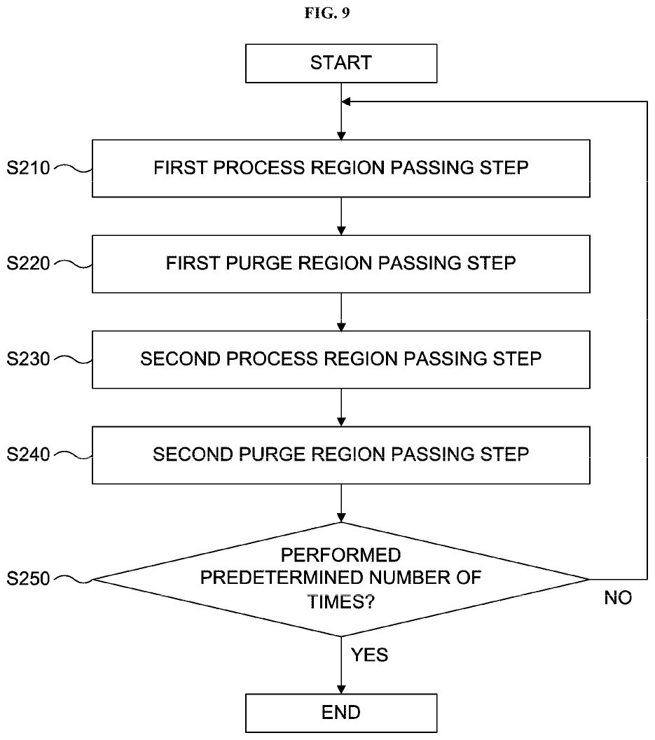

Subsequently, the substrate processing according to the first embodiment will be described with reference to FIGS. 8 and 9. FIG. 8 is a flow chart schematically illustrating the substrate processing according to the first embodiment described herein. FIG. 9 is a flow chart schematically illustrating a film-forming step of the substrate processing according to the first embodiment described herein. In the following description, the operations of the components of the substrate processing apparatus (and the reactor 200) are controlled by the controller 300.

The substrate processing according to the first embodiment will be described by way of an example in which a silicon nitride (SiN) film serving as the film is formed on the substrate S by using the Si₂H₂Cl₂ gas as the source gas and the NH₃ gas as the reactive gas.

A substrate loading and placing step S110 will be described. In the reactor 200, the pins 219 are elevated such that the pins 219 pass through the through-holes 217a of the rotary table 217. As a result, the pins 219 protrude from the surface of the rotary table 217 by a predetermined height. Subsequently, the gate valve 205 is opened, and the substrate S is placed on the pins 219 as shown in FIG. 3 by using a substrate transfer device (not shown). After the substrate S is placed on the pins 219, by lowering the pins 219, the substrate S is placed on one of the concave portions 217b.

The rotary table 217 is rotated until one of the concave portions 217b, where the substrate S is not placed, faces the gate valve 205. Thereafter, one of the substrates is placed on the above-mentioned one of the concave portions. The loading operation described above is repeated until the plurality of the substrates including the substrate S are placed on all of the concave portions 217b.

After the plurality of the substrates including the substrate S are placed on all of the concave portions 217b, the substrate transfer device is retracted out of the reactor 200, and the gate valve 205 is closed to seal the process vessel 203.

When the plurality of the substrates including the substrate S are loaded into the process chamber 201, it is preferable that the N₂ gas is supplied into the process chamber 201 by the first inert gas supply part 260 while exhausting the process chamber 201 by the exhaust parts 234 and 235. Thereby, it is possible to suppress the particles from entering the process chamber 201 and from adhering onto the plurality of the substrates including the substrate S. The vacuum pumps 234b and 235b may be continuously operated from the substrate loading and placing step S110 until at least a substrate unloading step S170 described later is completed.

When the substrate S is placed on the rotary table 217, the electric power is supplied to the heater 280 in advance such that a temperature (surface temperature) of the substrate S is adjusted to a predetermined temperature. For example, the predetermined temperature of the substrate S according to the first embodiment may range from the room temperature to 650° C., preferably from the room temperature to 400° C. The electric power may be continuously supplied to the heater 280 from the substrate loading and placing step S110 until at least the substrate unloading step S170 described later is completed.

In the substrate loading and placing step S110, the inert gas is supplied to the process vessel 203 and the heater mechanism 281 through the second inert gas supply part 270. The inert gas may be continuously supplied through the second inert gas supply part 270 from the substrate loading and placing step S110 until at least the substrate unloading step S170 described later is completed.

A step S120 of starting the rotation of the rotary table 217 will be described. After the plurality of the substrates including the substrate S are placed on all of the concave portions 217b, the controller 300 controls the rotating part 224 to rotate the rotary table 217 in the “R” direction shown in FIG. 1. By rotating the rotary table 217, the substrate S is moved to the first process region 206a, the first purge region 207a, the second process region 206b and the second purge region 207b sequentially in this order.

A step S130 of starting the supply of the gas will be described. When the substrate S is heated to a desired temperature and the rotary table 217 reaches a desired rotation speed, the valve 244 is opened to start the supply of the Si₂H₂Cl₂ gas into the first process region 206a. In parallel with the supply of the Si₂H₂Cl₂ gas, the valve 254 is opened to supply the NH₃ gas into the second process region 206b.

In the step S130, a flow rate of the Si₂H₂C1₂ gas is adjusted by the MFC 243 to a predetermined flow rate. For example, the predetermined flow rate of the Si₂H₂C1₂ gas in the step S130 may range from 50 sccm to 500 sccm.

In the step S130, a flow rate of the NH₃ gas is adjusted by the MFC 253 to a predetermined flow rate. For example, the predetermined flow rate of the NH₃ gas in the step S130 may range from 100 sccm to 5,000 sccm.

In addition, after the substrate loading and placing step S110, the process chamber 201 is exhausted by the exhaust parts 234 and 235 and the N₂ serving as the purge gas is supplied into the first purge region 207a and the second purge region 207b through the first inert gas supply part 260. In addition, by appropriately adjusting valve opening degrees of the APC valve 234c and the APC valve 235c, the inner pressure of the process chamber 201 is adjusted to a predetermined pressure.

A film-forming step S140 will be described. Here, a basic flow of the film-forming step S140 will be described, and the film-forming step S140 will be described in detail later. In the film-forming step S140, a silicon-containing layer is formed on the substrate S in the first process region 206a. After the substrate S is rotated to the second process region 206b, by reacting the silicon-containing layer with the NH₃ gas in the second process region 206b, a silicon nitride (SiN) film is formed on the substrate S. The rotary table 217 is rotated a predetermined number of times so that the SiN film of a desired thickness is obtained.

A step S150 of stopping the supply of the gas will be described. After the rotary table 217 is rotated the predetermined number of times, the valve 244 is closed to stop the supply of the Si₂H₂Cl₂ gas to the first process region 206a and the valve 254 is closed to stop the supply of the NH₃ gas to the second process region 206b.

A step S160 of stopping the rotation of the rotary table 217 will be described. After the supply of the Si₂H₂Cl₂ gas and the supply of the NH₃ gas are stopped according to the step S150, the rotation of the rotary table 217 is stopped in the step S160.

The substrate unloading step S170 will be described. The rotary table 217 is rotated to move the substrate S to the position facing the gate valve 205. Thereafter, the substrate S is supported on the pins 219 in the same manner as when the substrate S is loaded. After the substrate S is supported on the pins 219, the gate valve 205 is opened, and the substrate S is unloaded (transferred) out of the process vessel 203 using the substrate transfer device (not shown). The unloading operation described above is repeated until all of the plurality of the substrates are unloaded out of the process vessel 203. After all of the plurality of the substrates are unloaded, the supply of the inert gas by the first inert gas supply part 260 and the second inert gas supply part 270 is stopped.

Subsequently, the film-forming step S140 will be described in detail with reference to FIG. 9. The film-forming step S140 will be mainly described based on the substrate S among the plurality of the substrates placed on the rotary table 217 from a first process region passing step S210 to a second purge region passing step S240.

As shown in FIG. 9, during the film-forming step S140, the plurality of the substrates including the substrate S pass through the first process region 206a, the first purge region 207a, the second process region 206b and the second purge region 207b sequentially in this order as the rotary table 217 is rotated.

The first process region passing step S210 will be described. As the substrate S passes through the first process region 206a, the Si₂H₂C1₂ gas is supplied to the substrate S. When the substrate S passes through the first process region 206a, since there is no reactive gas in the first process region 206a, the Si₂H₂Cl₂ gas directly contacts (adheres) to the surface of the substrate S without reacting with the reactive gas. Thereby, the first layer is formed on the surface of the substrate S.

A first purge region passing step S220 will be described. After passing through the first process region 206a, the substrate S moves to the first purge region 207a. When the substrate S passes through the first purge region 207a, components of the Si₂H₂Cl₂ gas which are not strongly adhered to the substrate S in the first process region 206a are removed from the substrate S by the inert gas.

A second process region passing step S230 will be described. After passing through the first purge region 207a, the substrate S moves to the second process region 206b. When the substrate S passes through the second process region 206b, the first layer reacts with the NH₃ gas serving as the reactive gas in the second process region 206b. Thereby, a second layer containing at least silicon (Si) and nitrogen (N) is formed on the substrate S.

The second purge region passing step S240 will be described. After passing through the second process region 206b, the substrate S moves to the second purge region 207b. When the substrate S passes through the second purge region 207b, gases such as HCl desorbed from the second layer on the substrate S in the second process region 206b and surplus H₂ gas are removed from the substrate S by the inert gas.

As described above, at least two gases reacting with each other are sequentially supplied to the substrate S. A cycle of the first embodiment includes the first process region passing step S210, the first purge region passing step S220, the second process region passing step S230 and the second purge region passing step S240.

A determination step S250 will be described. In the determination step S250, the controller 300 determines whether the cycle including the first process region passing step S210, the first purge region passing step S220, the second process region passing step S230 and the second purge region passing step S240 has been performed a predetermined number of times. Specifically, the controller 300 counts the number of the rotation of the rotary table 217.

When the cycle has not been performed the predetermined number of times (“NO” in FIG. 9), the rotary table 217 is rotated and the cycle including the first process region passing step S210, the first purge region passing step S220, the second process region passing step S230 and the second purge region passing step S240 is repeated. By performing the cycle the predetermined number of times, it is possible to form the film on the substrate S.

When the cycle has been performed the predetermined number of times (“YES” in FIG. 9), the film-forming step S140 is terminated. As described above, it is possible to form the film on the substrate S with a predetermined thickness by performing the cycle the predetermined number of times

### (3) Effects according to First Embodiment

According to the first embodiment described above, it is possible to provide at least one or more of the following effects.

(a) It is possible to suppress a non-uniformity of the film formed on the substrate S due to the thermal decomposition of the source gas in the nozzle. That is, it is possible to improve the uniformity of the thickness of the film formed on the surface of the substrate S.

(b) By configuring the return path portion 245c to be displaced circumferentially from the forward path portion 245a along the counter-rotational direction of the rotary table 217, it is possible to lengthen the residence time of the source gas in the first process region 206a.

(c) By configuring the front end of the return path portion 245c which is at the downstream end of the gas flow to extend to the vicinity of the exhaust groove 288 connected to the exhaust port 291 configured to exhaust the source gas, it is possible to shorten the residence time of the thermally decomposed source gas on the substrate S to thereby reduce its influence on the thickness of the film.

(d) By configuring some of the holes 255a to vertically face the substrate S on the rotary table 217 and the other of the holes 255a to be located vertically above the outside of the substrate S and configuring some of the holes 255c to vertically face the substrate S on the rotary table 217 and the other of the holes 255c to be located vertically above the outside of the substrate S, it is possible to uniformly form the film up to the edge (end portion) of the substrate S.

(e) By setting the inner diameter t₂ of the bent portion 245b greater than the inner diameter t₁ of the forward path portion 245a and the return path portion 245c, it is possible to reduce the pressure loss of the source gas at the bent portion 245b.

### (4) Other Embodiments

While the first embodiment is described in detail, the above-described technique is not limited thereto. For example, features such as the shape of the nozzle 245, the shape of the hole and the size of the hole are not limited to the first embodiment described above. For example, the features may be modified as in the following embodiments. Hereinafter, the following embodiments will be mainly described based on the differences between the first embodiment and the following embodiments. According to the following embodiments, it is possible to obtain the same effects as those of the first embodiment.

### Second Embodiment

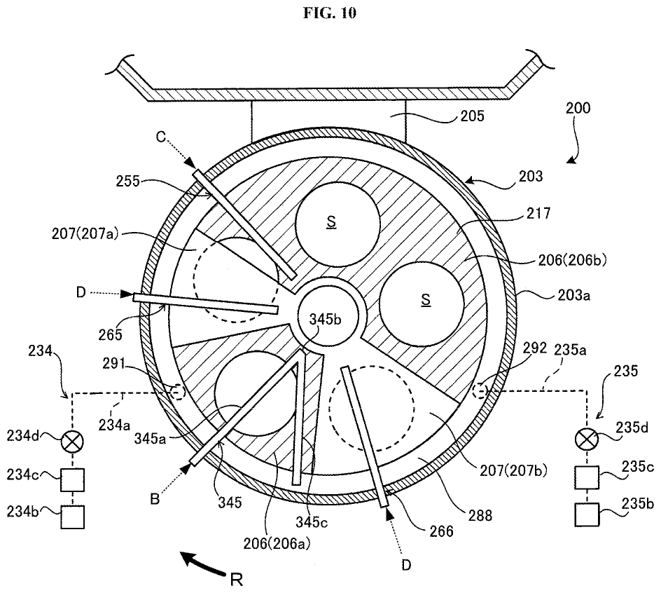

According to a second embodiment, as shown in FIG. 10, a nozzle 345 of a different shape from the nozzle 245 is used instead of the nozzle 245 described above.

The nozzle 345 may be embodied by a V-shaped nozzle. The nozzle 345 includes: a forward path portion 345a connected to and communicated with the gas supply pipe 241; a bent portion 345b bent from the forward path portion 345a to communicate with the forward path portion 345a; and a return path portion 345c connected to and communicated with the bent portion 345b. That is, the bent portion 345b connects the forward path portion 345a and the return path portion 345c. The center of the rotary table 217 is disposed on an extension line of the forward path portion 345a. The forward path portion 345a and the return path portion 345c are provided in a V shape.

The forward path portion 345a extends along the radial direction of the rotary table 217 from the wall 203a of the process vessel 203 toward the center portion of the rotary table 217. In addition, a front end of the forward path portion 345a, which is at the downstream end of the gas flow in the forward path portion 345a, extends beyond the edge of the substrate S on the rotary table 217.

The bent portion 345b is disposed at a position vertically facing an outside of the substrate S placed on the rotary table 217. That is, the bent portion 345b does not overlap with the substrate S placed on the rotary table 217 when viewed from above.

The return path portion 345c extends along the radial direction of the rotary table 217 from the center portion of the rotary table 217 toward the wall 203a of the process vessel 203. A front end of the return path portion 345c, which is at the downstream end of the gas flow in the return path portion 345c, extends to the exhaust groove 288 provided outside the edge of the substrate S on the rotary table 217. The return path portion 345c is displaced circumferentially from the forward path portion 345a along a counter-rotational direction of the rotary table 217.

By configuring the forward path portion 345a and the return path portion 345c to extend along the radial direction of the rotary table 217 as described above, it is possible to easily adjust a thickness distribution of the film. Similar to the forward path portion 245a and the return path portion 245c describe above, the plurality of the holes 255a are provided at the forward path portion 345a to vertically face the substrate S on the rotary table 217 and the plurality of the holes 255c are provided at the return path portion 345c to vertically face the substrate S on the rotary table 217.

### Third Embodiment

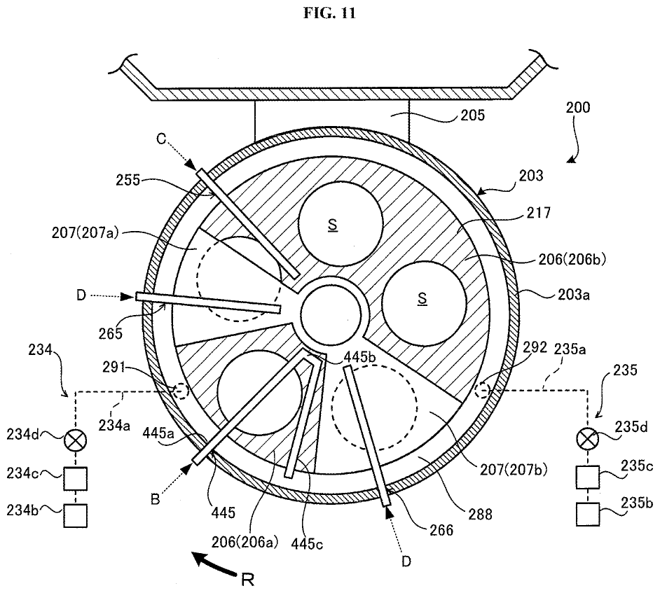

According to a third embodiment, as shown in FIG. 11, a nozzle 445 of a different shape from the nozzle 245 is used instead of the nozzle 245 described above.

The nozzle 445 includes: a forward path portion 445a connected to and communicated with the gas supply pipe 241; a bent portion 445b bent from the forward path portion 445a to communicate with the forward path portion 445a; and a return path portion 445c connected to and communicated with the bent portion 445b. That is, the bent portion 445b connects the forward path portion 445a and the return path portion 445c. The center of the rotary table 217 is disposed on extension lines of the forward path portion 445a and the return path portion 445c. The forward path portion 445a and the return path portion 445c are provided in a V shape by being bent at the bent portion 445b.

The forward path portion 445a extends along the radial direction of the rotary table 217 from the wall 203a of the process vessel 203 toward the center portion of the rotary table 217. In addition, a front end of the forward path portion 445a, which is at the downstream end of the gas flow in the forward path portion 445a, extends beyond the edge of the substrate S on the rotary table 217.

The bent portion 445b is disposed at a position vertically above the outside of the substrate S placed on the rotary table 217. That is, the bent portion 445b does not overlap with the substrate S placed on the rotary table 217 when viewed from above.

The return path portion 445c extends along the radial direction of the rotary table 217 from the center portion of the rotary table 217 to the wall 203a of the process vessel 203. A front end of the return path portion 445c, which is at the downstream side of the gas flow in the return path portion 445c, extends to the exhaust groove 288 provided outside the edge of the substrate S on the rotary table 217. The return path portion 445c is displaced circumferentially from the forward path portion 445a along a counter-rotational direction side of the rotary table 217.

Similar to the forward path portion 245a and the return path portion 245c describe above, the plurality of the holes 255a are provided at the forward path portion 445a to vertically face the substrate S on the rotary table 217 and the plurality of the holes 255c are provided at the return path portion 445c to vertically face the substrate S on the rotary table 217.

### Fourth Embodiment

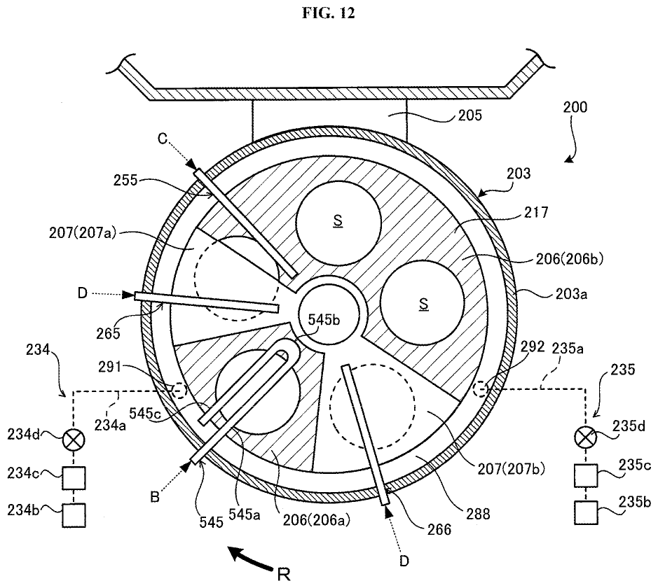

According to a fourth embodiment, as shown in FIG. 12, a nozzle 545 of a different shape from the nozzle 245 is used instead of the nozzle 245 described above.

The nozzle 545 may be embodied by a U-shaped nozzle. The nozzle 545 includes: a forward path portion 545a connected to and communicated with the gas supply pipe 241; a bent portion 545b bent from the forward path portion 545a to communicate with the forward path portion 545a; and a return path portion 545c connected to and communicated with the bent portion 545b. That is, the bent portion 545b connects the forward path portion 545a and the return path portion 545c. The return path portion 545c is provided in parallel with the forward path portion 545a. Similar to the forward path portion 245a and the return path portion 245c describe above, the plurality of the holes 255a are provided at the forward path portion 545a to vertically face the substrate S on the rotary table 217 and the plurality of the holes 255c are provided at the return path portion 545c to vertically face the substrate S on the rotary table 217.

The return path portion 545c of the nozzle 545 is displaced circumferentially from the forward path portion 545a along a rotational direction of the rotary table 217. In addition, a front end of the return path portion 545c, which is at the downstream end of the gas flow in the return path portion 545c, is located in the vicinity of the exhaust port 291

Since the thermally decomposed source gas flows through the return path portion 545c, the thickness of the film tends to increase at portions of the substrate S facing the return path portion 545c. By providing the front end of the return path portion 545c, which is at the downstream end of the gas flow in the return path portion 545c, to be located in the vicinity of the exhaust port 291, it is possible to shorten the residence time of the thermally decomposed source gas on the substrate S to thereby reduce its influence on the thickness of the film.

### Fifth Embodiment

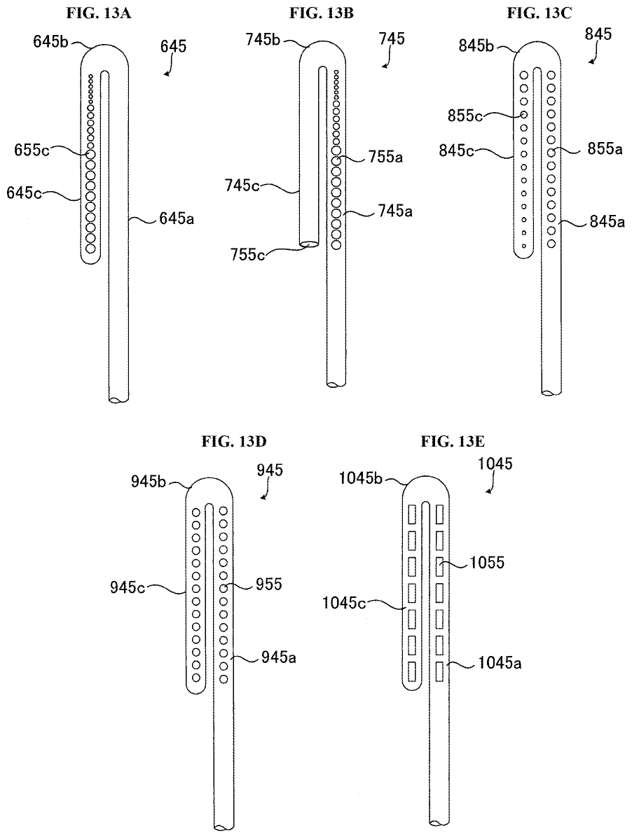

According to a fifth embodiment, as shown in FIG. 13A, a nozzle 645 is used instead of the nozzle 245 described above. According to the fifth embodiment, a plurality of holes 655c different from the plurality of the holes 255c are provided at the nozzle 645.

The nozzle 645 includes: a forward path portion 645a connected to and communicated with the gas supply pipe 241; a bent portion 645b bent from the forward path portion 645a to communicate with the forward path portion 645a; and a return path portion 645c connected to and communicated with the bent portion 645b. That is, the bent portion 645b connects the forward path portion 645a and the return path portion 645c in a U shape. The return path portion 645c is provided in parallel with the forward path portion 645a.

According to the fifth embodiment, the forward path portion 645a is not provided with a hole facing the substrate S on the rotary table 217

The plurality of the holes 655c are provided at the return path portion 645c to vertically face the substrate S on the rotary table 217. A diameter of each of the holes 655c gradually increases from the upstream side to the downstream side of the gas flow in the return path portion 645c. That is, the diameter of each of the holes 655c gradually increases as a distance from the bent portion 645b increases.

That is, the diameters of the holes 655c are greater at locations vertically above the outer peripheral portion of the rotary table 217 than at locations vertically above the center portion of the rotary table 217. Thereby, it is possible to increase the amount of the thermally decomposed source gas exposed to the substrate S.

### Sixth Embodiment

According to a sixth embodiment, as shown in FIG. 13B, a nozzle 745 is used instead of the nozzle 245 described above. According to the sixth embodiment, a plurality of holes 755a different from the plurality of the holes 255a are provided at the nozzle 745.

The nozzle 745 includes: a forward path portion 745a connected to and communicated with the gas supply pipe 241; a bent portion 745b bent from the forward path portion 745a to communicate with the forward path portion 745a; and a return path portion 745c connected to and communicated with the bent portion 745b.

The plurality of the holes 755a are provided at the forward path portion 745a to vertically face the substrate S on the rotary table 217. A diameter of each of the holes 755a gradually decreases from the upstream side to the downstream side of the gas flow in the forward path portion 745a. That is, the diameters of the holes 755a gradually decrease as a distance from the bent portion 745b decreases. In other words, the diameters of the holes 755a are greater at locations vertically above the outer peripheral portion of the rotary table 217 than at locations vertically above the center portion of the rotary table 217. Thereby, it is possible to increase the amount of the thermally decomposed source gas exposed to the substrate S.

In addition, an opening 755c is provided at a front end of the return path portion 745c which is at the downstream end of the gas flow in the return path portion 745c. That is, the return path portion 745c is not provided with a hole facing the substrate S on the rotary table 217, and the opening 755c is provided at the front end of the return path portion 745c. That is, a front end of the nozzle 745 is open. Thereby, it is possible to exhaust the thermally decomposed source gas. That is, it is possible to supply the source gas that has not been thermally decomposed onto the substrate S to thereby exhaust the thermally decomposed source gas.

### Seventh Embodiment

According to a seventh embodiment, as shown in FIG. 13C, a nozzle 845 is used instead of the nozzle 245 described above. According to the seventh embodiment, a plurality of holes 855a different from the plurality of the holes 255a and a plurality of holes 855c different from the plurality of the holes 255c are provided at the nozzle 845.

The nozzle 845 includes: a forward path portion 845a connected to and communicated with the gas supply pipe 241; a bent portion 845b bent from the forward path portion 845a to communicate with the forward path portion 845a; and a return path portion 845c connected to and communicated with the bent portion 845b.

The plurality of the holes 855a are provided at the forward path portion 845a to vertically face the substrate S on the rotary table 217. The diameters of the holes 855a are all the same.

The plurality of the holes 855c are provided at the return path portion 845c to vertically face the substrate S on the rotary table 217. The diameters of the holes 855c gradually decrease from the upstream side to the downstream side of the gas flow in the return path portion 845c. Thereby, it possible to prevent the thermally decomposed source gas from being supplied onto the substrate S.

### Eighth Embodiment

According to an eighth embodiment, as shown in FIG. 13D, a nozzle 945 is used instead of the nozzle 245 described above. According to the eighth embodiment, a plurality of holes 955 different from the plurality of the holes 255a and different from the plurality of the holes 255c are provided at the nozzle 945.

The nozzle 945 includes: a forward path portion 945a connected to and communicated with the gas supply pipe 241; a bent portion 945b bent from the forward path portion 945a to communicate with the forward path portion 945a; and a return path portion 945c connected to and communicated with the bent portion 945b.

The plurality of the holes 955 are provided at the forward path portion 945a and at the return path portion 945c to vertically face the substrate S on the rotary table 217. The diameters of the holes 955 are all the same.

### Ninth Embodiment

According to a ninth embodiment, as shown in FIG. 13E, a nozzle 1045 is used instead of the nozzle 245 described above. According to the eighth embodiment, a plurality of holes 1055 different from the plurality of the holes 255a and different from the plurality of the holes 255c are provided at the nozzle 1045.

The nozzle 1045 includes: a forward path portion 1045a connected to and communicated with the gas supply pipe 241; a bent portion 1045b bent from the forward path portion 1045a to communicate with the forward path portion 1045a; and a return path portion 1045c connected to and communicated with the bent portion 1045b.

The plurality of the holes 1055 of a slit shape are provided at the forward path portion 1045a and at the return path portion 1045c to vertically face the substrate S on the rotary table 217. The holes 1055 of the forward path portion 1045a are located at radial positions substantially same as those of the holes 1055 of the return path portion 1045c with reference to the radial direction of the rotary table 217. In addition, an opening (not shown) may be provided at a front end of the return path portion 1045c which is at the downstream end of the gas flow in the return path portion 1045c.

While the technique is described in detail by way of the above-described embodiments, the above-described technique is not limited thereto. The above-described technique may be modified in various ways without departing from the gist thereof.

For example, the above-described embodiment are described by way of an example in which the plurality of the holes of a round shape or a slit shape are provided at the nozzle configured to supply the source gas. However, the above-described technique is not limited thereto. For example, the plurality of the holes of a round shape or a slit shape may be replaced by a plurality of holes of an elongated shape.

For example, the above-described first embodiment are described by way of an example in which the plurality of the holes 255a provided at the forward path portion 245a and the plurality of the holes 255c provided at the return path portion 245c are provided at substantially the same positions in the radial direction of the rotary table 217. However, the above-described technique is not limited thereto. For example, the number of the holes 255a provided at the forward path portion 245a may be different from the number of the holes 255c provided at the return path portion 245c. In addition, when a gas such as disilicon hexachloride (Si₂Cl₆) that is easily thermally decomposed is used as the source gas, the diameters of the holes 255a of the forward path portion 245a may gradually increase from the upstream side to the downstream side of the gas flow in the forward path portion 245a, and the diameters of the holes 255c of the return path portion 245c may gradually decrease from the upstream side to the downstream side of the gas flow in the return path portion 245c. In addition, when such gas that is difficult to thermally decompose is used as the source gas, the diameters of the holes 255a of the forward path portion 245a may increase whereas the diameters of the holes 255c of the return path portion 245c may gradually decrease from the upstream side to the downstream side of the gas flow in the return path portion 245c. As the gas that is difficult to thermally decompose, tetrachlorotitanium (TiCl₄) gas may be used.

For example, the above-described embodiments are described by way of an example in which the U-shaped nozzle or the V-shaped nozzle is used as the gas supply nozzle configured to supply the source gas. However, the above-described technique is not limited thereto. For example, a plurality of U-shaped nozzles or a plurality of V-shaped nozzles may be provided to supply the source gas. For example, the I-shaped nozzle may be combined with the U-shaped nozzle or the V-shaped nozzle to supply the source gas.

For example, the above-described embodiments are described by way of an example in which the SiN film serving as a nitride film is formed on the substrate S by using the Si₂H₂Cl₂ gas as the source gas and the NH₃ gas as the reactive gas. However, the above-described technique is not limited thereto. For example, instead of the Si₂H₂Cl₂ gas, a gas such as SiH₄, Si₂H₆, Si₃H₈, aminosilane and TSA gas may be used as the source gas. For example, O₂ gas may be used as the reactive gas instead of the NH₃ gas to form an oxide film instead of the nitride film. The above-described technique may also be applied to form various films on the substrate S. For example, a nitride film such as a tantalum nitride (TaN) film and a titanium nitride (TiN) film, an oxide film such as a hafnium dioxide (HfO) film, a zirconium oxide (ZrO) film, a titanium oxide (TiO) film and a silicon oxide (SiO) film or a metal film containing a metal element such as ruthenium (Ru), nickel (Ni) and tungsten (W) may be formed on the substrate S according to the above-described technique. When the TiN film or the TiO film is formed, for example, a gas such as tetrachlorotitanium (TiCl₄) gas may be used as the source gas.

According to some embodiments in the present disclosure, it is possible to improve the uniformity of the characteristics of the film formed on the substrate by the rotary type apparatus.

1. A substrate processing apparatus configured to process a substrate by supplying a process gas, the substrate processing apparatus comprising:
a process vessel provided with a plurality of process regions in which the substrate is processed;
a rotary table provided in the process vessel to be rotatable about a point outside the substrate so as to enable the substrate to sequentially pass through the plurality of the process regions, the substrate being placed on the rotary table; and
a gas supply nozzle comprising:
a forward path portion provided in at least one of the plurality of the process regions and extending from a wall of the process vessel toward a center portion of the rotary table to face a surface of the rotary table; and
a return path portion connected with the forward path portion via a bent portion and extending from the center portion of the rotary table toward the wall of the process vessel to face the surface of the rotary table,
wherein a downstream end of the forward path portion of the gas supply nozzle extends beyond an edge of a concave portion in which the substrate sits, and a front end of the return path portion extends to an exhaust groove outside the rotary table.

2. (canceled)

3. The substrate processing apparatus of claim 1, wherein the front end of the return path portion of the gas supply nozzle, located at the downstream end of the gas flow in the return path portion, extends to a vicinity of the exhaust groove configured to exhaust the process gas.

4. (canceled)

5. The substrate processing apparatus of claim 1, wherein the return path portion extends along a radial direction of the rotary table in parallel with a diameter of the substrate.

6. The substrate processing apparatus of claim 1, wherein the return path portion is displaced circumferentially from the forward path portion along a counter-rotational direction of the rotary table.

7. The substrate processing apparatus of claim 1, wherein the return path portion is displaced circumferentially from the forward path portion along a rotational direction of the rotary table.

8. The substrate processing apparatus of claim 1, wherein the bent portion is located at a position vertically facing the center portion of the rotary table located closer to a center of the rotary table than a substrate placement region of the rotary table is located.

9. The substrate processing apparatus of claim 1, wherein an inner diameter of the bent portion is greater than an inner diameter of the forward path portion and an inner diameter of the return path portion.

10. The substrate processing apparatus of claim 1, wherein a plurality of holes are provided at the return path portion, and sizes of the holes are greater at locations vertically above an outer peripheral portion of the rotary table than at locations vertically above the center portion of the rotary table.

11. The substrate processing apparatus of claim 1, wherein a plurality of holes are provided at the forward path portion, and sizes of the holes are greater at locations vertically above an outer peripheral portion of the rotary table than at locations vertically above the center portion of the rotary table.

12. The substrate processing apparatus of claim 1, wherein each of the forward path portion and the return path portion is provided with a plurality of holes, sizes of each of the holes provided at the forward path portion gradually increases from an upstream side to a downstream side, and a size of each of the holes provided at the return path portion gradually decreases from an upstream side to a downstream side.

13. The substrate processing apparatus of claim 1, wherein an opening is provided at a front end of the return path portion and no opening is provided elsewhere at the return path portion.

14. The substrate processing apparatus of claim 1, wherein no hole is provided at the forward path portion, and a plurality of holes are provided at the return path portion.

15. The substrate processing apparatus of claim 1, wherein a plurality of holes provided at the forward path portion and at the return path portion are located at positions vertically facing the substrate.

16. The substrate processing apparatus of claim 1, wherein a plurality of holes are provided at each of the forward path portion and the return path portion, and the holes of the forward path portion are located at radial positions substantially same as those of the holes of the return path with reference to a radial direction of the rotary table.

17. (canceled)

18. The substrate processing apparatus of claim 1, wherein number of holes provided at the forward path portion is different from number of holes provided at the return path portion.

19. The substrate processing apparatus of claim 15, wherein the plurality of the holes are located at positions radially outer than the substrate on the rotary table.

20. The substrate processing apparatus of claim 20, wherein the front end of the return path portion comprises an opening.

21. The substrate processing apparatus of claim 1, wherein each of the forward path portion and the return path portion comprises a plurality of holes provided at positions vertically facing the substrate on the rotary table.
